(19) United States
(12) Patent Application Publication
(10) Pub. No.: US 2004/0202442 A1
(43) Pub. Date: Oct. 14, 2004

(54) Multichannel photocoupler

(76) Inventor: Atsushi Murayama, Nabari-shi (JP)

Correspondence Address: BIRCH STEWART KOLASCH & BIRCH, PO BOX 747, FALLS CHURCH, VA, 22040-0747, US

(21) Appl. No.: 10/820,030

(22) Filed: Apr. 8, 2004

(30) Foreign Application Priority Data
Apr. 11, 2003 (JP) 2003-107939

(51) Int. Cl. G02B 6/00; H03K 5/12

(52) U.S. Cl. 385/147

(57) ABSTRACT

Input side(s) is/are made up of input signal coupling circuit(s) subjecting input signal(s) at respective channel(s) to time division so as to form a single consolidated signal, and a single light-emitting element communicating such signal to output side(s); output side(s) is/are made up of a single light-receiving element receiving time-divided signal(s) from light-emitting element(s) at input side(s), amplifier circuit(s) carrying out amplification of received time-divided signal(s) so as to obtain constant level(s), and output signal separation circuit(s) decoding amplified time-divided signal(s) and outputting same to respective channel(s).

### BACKGROUND OF INVENTION

This application claims priority under 35 USC 119(a) to Patent Application No. 2003-107939 filed in Japan on 11 Apr. 2003, the content of which is incorporated herein by reference in its entirety.

The present invention pertains to multichannel photocoupler-, photothyristor-coupler-, and/or phototriac-coupler-type photocouplers in which light-emitting element(s) and light-receiving element(s) are optically coupled.

Multichannel photocouplers equipped with light-receiving element(s) that turn ON when light is received from light-emitting element(s) have been proposed conventionally (e.g., see Japanese Patent Application Publication Kokai No. S58-168284 (1983) and Japanese Patent Application Publication Kokai No. H4-72812 (1992)).

As an example of a conventional multichannel photocoupler, FIG. 11 shows an equivalent circuit for a 4-channel phototransistor-type photocoupler.

This photocoupler has, at the input side thereof, light-emitting elements 1a through 1d; and has, at the output side thereof, phototransistor elements 2a through 2d that turn ON when light from light-emitting elements 1a through 1d is received. At this photocoupler, when electric current is made to flow through light-emitting elements 1a through 1d at the input side thereof, light-emitting elements 1a through 1d emit light; and upon receiving that light, electric current is made able to flow through phototransistor elements 2a through 2d at the output side thereof.

With such a conventional multichannel photocoupler there has been the problem that light-emitting elements and light-receiving elements have been required in quantities proportional to the number of channels, causing increase in the overall circuit parts count, increase in the size of the photocoupler package, increase in the number of pins, and increase in price. Moreover, there has been the problem that increased surface area is required when mounting such an photocoupler to a board in electronic equipment or the like.

The present invention was conceived in order to solve such problems, it being an object thereof to provide a multichannel photocoupler addressing the need that there be as many light-emitting elements and light-receiving elements as there are channels in conventional multichannel photocouplers, and permitting decrease in overall circuit parts count, decrease in number of pins, and decrease in size of photocoupler package as a result of consolidation of light-emitting elements and light-receiving elements into a single one each thereof.

### SUMMARY OF INVENTION

In order to solve the foregoing and/or other problems, a multichannel photocoupler in accordance with one or more embodiments of the present invention is such that input side(s) is/are made up of input signal coupling circuit(s) serving as time division means subjecting input signal(s) at respective channel(s) to time division so as to form a single consolidated signal, and a single light-emitting element communicating such signal to output side(s); and is such that output side(s) is/are made up of a single light-receiving element receiving time-divided signal(s) from light-emitting element(s) at input side(s), and output signal separation circuit(s) serving as output signal separation means decoding such signal(s) and outputting same to respective channel(s).

Furthermore, such an photocoupler may further comprise synchronization means for, in the event that signal(s) at respective channel(s) is/are transferred from input side(s) to output side(s), synchronizing such signal(s) through use of prescribed clock(s). Such synchronization means may facilitate encoding and decoding of time-divided signal(s). Furthermore, synchronization means at input side(s), in the event that input signal(s) at respective channel(s) is/are subjected to time division through use of prescribed clock(s), may generate start bit(s) before signal(s) at first channel(s); and synchronization means at output side(s) may possess functionality for detecting start bit(s). This may prevent bits from being dropped due to influence of noise or the like where input signal state(s) at respective channel(s) is/are subjected to time division.

In such case, in one method of transferring clock synchronization signal(s) from input side(s) to output side(s), transfer is accomplished through use of clock-signal-transfer light-emitting element(s) and light-receiving element(s) separate from signal-transfer light-emitting element(s) and light-receiving element(s).

Furthermore, in another method, signal-transfer light-emitting element(s) and light-receiving element(s) also serve as means for transferring clock synchronization signal(s), clock synchronization signal(s) being transferred simultaneous with signal(s) at respective channel(s). In such case, a method might be employed in which, at input side(s), clock synchronization signal(s) and signal(s) at respective channel(s) being transferred from input side(s) to output side(s) are transferred to output side(s) such that electric current(s) flowing at light-emitting element(s) is/are varied so as to impart difference(s) in optical intensity or intensities; and, at output side(s), signal(s) received at light-receiving element(s) and having differences in optical intensity or intensities is/are separated into signal(s) at respective channel(s) and clock synchronization signal(s).

Furthermore, a multichannel photocoupler in accordance with one or more embodiments of the present invention is such that input side(s) is/are made up of a single light-emitting element transferring signal(s) to output side(s), and input signal coupling circuit(s) serving as level coupling means carrying out level coupling with respect to input signal(s) at respective channel(s) so as to impart change(s) in optical intensity or intensities at light-emitting element(s) and causing same to be transferred to output side(s); and is such that output side(s) is/are made up of a single light-receiving element receiving signal(s) imparted with change(s) in optical intensity or intensities from light-emitting element(s), and output signal separation circuit(s) decoding such signal(s) and outputting same to respective channel(s).

In such case, it is conceivable that change(s) over time in optical intensity or intensities at light-emitting element(s) could cause optical signal(s) that is/are transferred to output side(s) to change from initial value(s), preventing same from being separated into prescribed respective channel(s). For this reason, a constitution may be adopted in which separate light-receiving element(s) monitoring optical intensity or intensities at light-emitting element(s) is/are provided at input side(s), change(s) over time in optical intensity or intensities at light-emitting element(s) being fed back to level coupling means so as to make it possible for optical intensity or intensities produced by light-emitting element(s) to always be accurately separated into signal(s) at respective channel(s).

### BRIEF DESCRIPTION OF DRAWINGS

FIG. 1 is an equivalent circuit indicating a first embodiment of a 4-channel photocoupler associated with a multichannel photocoupler in accordance with the present invention.

FIG. 2 is an equivalent circuit indicating a second embodiment of a multichannel photocoupler associated with the present invention.

FIG. 3 is an equivalent circuit indicating a fifth embodiment of a 4-channel photocoupler associated with the present invention.

FIG. 4 is an equivalent circuit indicating a sixth embodiment of a 4-channel photocoupler associated with the present invention.

FIG. 5 is an equivalent circuit for a working example of an output stage in an output signal separation circuit associated with the present invention.

FIG. 6 is an equivalent circuit for another working example of an output stage in an output signal separation circuit associated with the present invention.

FIG. 7 is an equivalent circuit for yet another working example of an output stage in an output signal separation circuit associated with the present invention.

FIG. 8 is a timing chart indicating operation in an example of operation in a multichannel photocoupler in accordance with the present invention.

FIG. 9 is a timing chart indicating operation in another example of operation in a multichannel photocoupler in accordance with the present invention.

FIG. 10 is an explanatory diagram showing a light-emitting element→light-receiving element signal level table for explaining another example of operation in a multichannel photocoupler in accordance with the present invention.

FIG. 11 is an equivalent circuit indicating an example of a conventional multichannel photocoupler.

### DESCRIPTION OF PREFERRED EMBODIMENTS

Below, embodiments of the present invention are described with reference to the drawings.

Embodiment 1

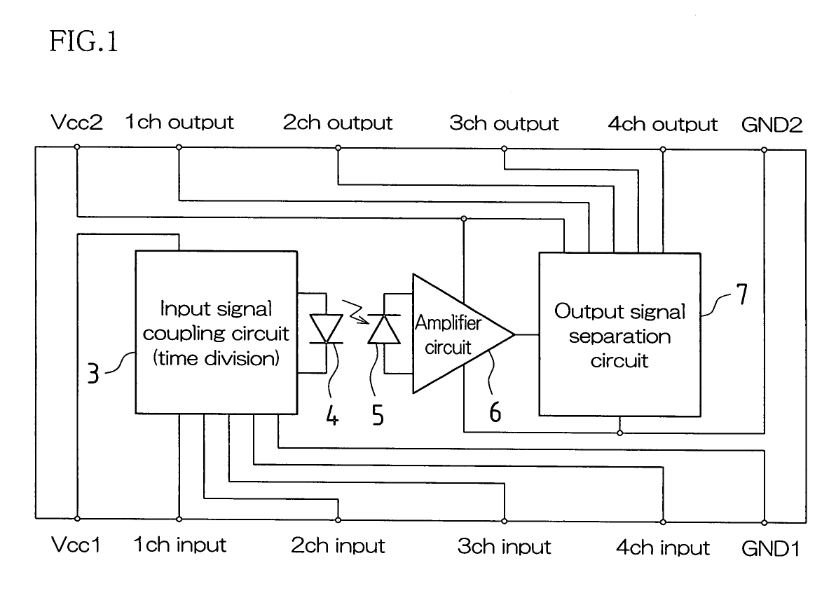

FIG. 1 is an equivalent circuit indicating a first embodiment of a 4-channel photocoupler associated with the present invention.

In an photocoupler in accordance with the present first embodiment, the input side thereof is made up of input signal coupling circuit 3 subjecting input signals at respective channels to time division so as to form a single consolidated signal, and a single light-emitting element 4 communicating such signal to the output side thereof; and the output side thereof is made up of a single light-receiving element 5 receiving a time-divided signal from light-emitting element 4 at the input side thereof, amplifier circuit 6 carrying out amplification of received the time-divided signal so as to obtain constant level(s), and output signal separation circuit 7 decoding the amplified time-divided signal and outputting same to respective channels.

As a result of employment of an photocoupler constituted in such fashion, input signal states at respective channels at input terminals “1ch input” through “4ch input” for the four channels at the input side are subjected to time division at input signal coupling circuit 3 so as to be consolidated into a single signal (time-divided signal) that is converted into an optical signal at light-emitting element 4 which represents the next stage, and this is then transferred to the output side. In addition, this time-divided signal is received at light-receiving element 5 at the output side; that signal is at amplifier circuit 6, which represents the next stage, amplified so as to obtain constant level; and the time-divided signal is at output signal separation circuit 7 thereafter decoded and separated into four channels of output signals that are output to output terminals “1ch output” through “4ch output” for the corresponding respective channels.

Embodiment 2

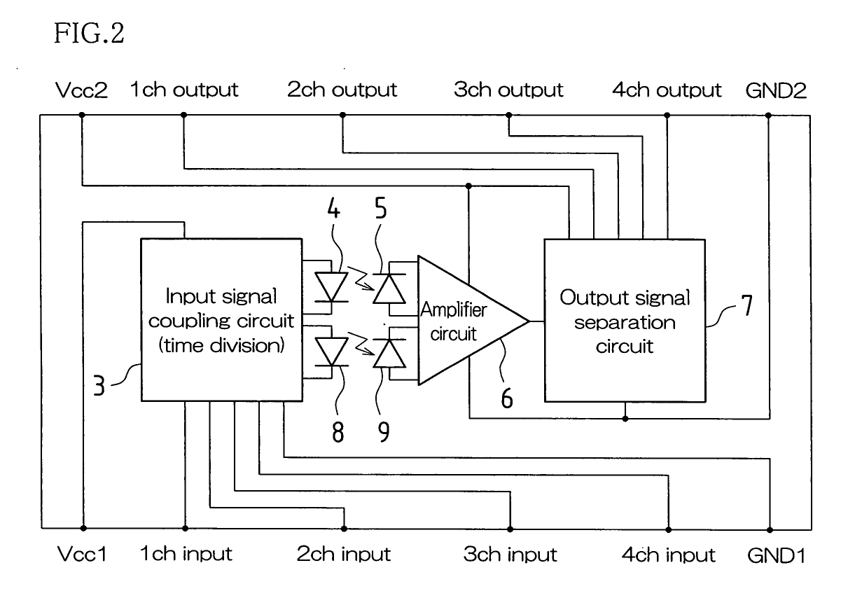

FIG. 2, being an equivalent circuit for a 4-channel photocoupler provided with means for carrying out synchronization with respect to prescribed clock signal CK, shows a second embodiment of a multichannel photocoupler in accordance with the present invention.

The photocoupler of the present second embodiment, in the context of the photocoupler of the foregoing first embodiment, is provided, at the input side thereof, with a single clock-signal-transfer light-emitting element 8 other than signal-transfer light-emitting element 4; and is provided, at the output side thereof, with a single clock-signal-transfer light-receiving element 9 other than signal-transfer light-receiving element 5. As the constitution of the present embodiment is in other respects identical to that of the first embodiment, like reference numerals will be used herein for like components.

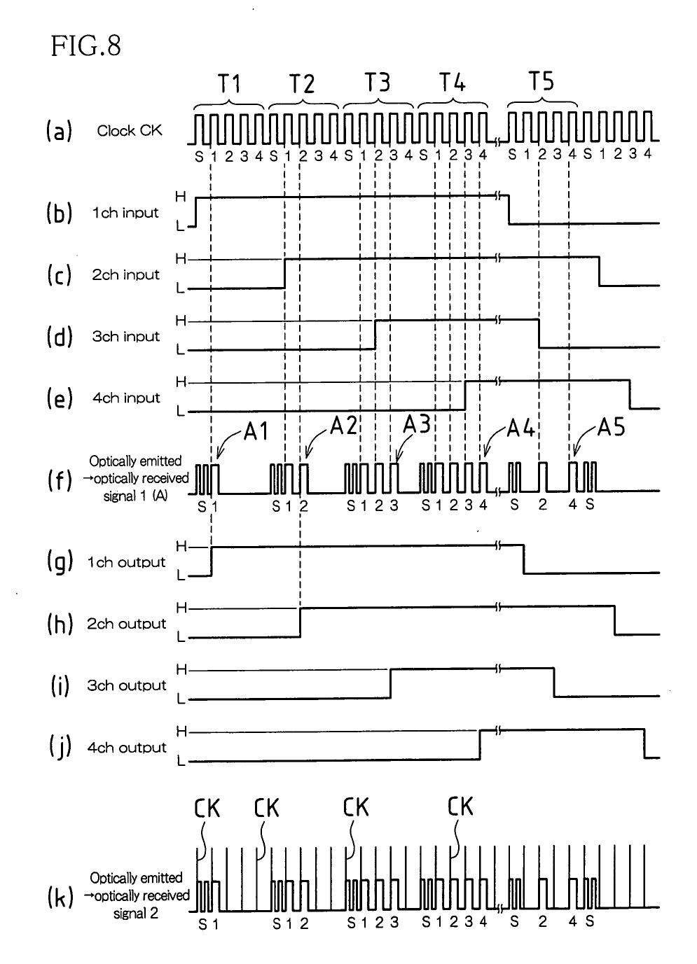

Next, referring to the timing chart shown in FIG. 8, operation of a 4-channel photocoupler having the foregoing constitution is described in specific terms.

First, clock signal CK (FIG. 8(a)) carries out input and output clock synchronization, being transferred from input side to output side by clock-signal-transfer light-emitting element 8 and clock-signal-transfer light-receiving element 9 shown in FIG. 2.

Next, input signal coupling circuit 3 uses respective rising edges “1” through “4” of clock signal CK to detect states of input signals (FIG. 8(b) through FIG. 8(e)) at respective channels at input terminals “1ch input” through “4ch input” for the four channels at the input side, time-divided signal A being generated after the fashion of the waveform shown at “light-emitting element→light-receiving element signal 1” at FIG. 8(f) based on whether the level at the input terminal for each channel is at such time “L” or “H.”

That is, with respect to respective rising edges “1” through “4” at clock signal CK during interval T1, because the level at “1ch input” is “H” but the levels at the remaining “2ch input” through “4ch input” are “L,” the time-divided signal during this interval will, as indicated at A1 in the drawing, be such that “S,” serving as start bit at the clock signal (described below), precedes a sequence in which the level of only “1ch input” (corresponding to “1” at clock signal CK) is “H” but the levels of the remaining “2ch input” through “4ch input” are “L.”

Furthermore, with respect to respective rising edges “1” through “4” at the clock signal during interval T2, because the levels at “1ch input” and “2ch input” are “H” but the levels at the remaining “3ch input” and “4ch input” are “L,” the time-divided signal during this interval will, as indicated at A2 in the drawing, be such that “S,” serving as start bit at the clock signal, precedes a sequence in which the levels of “1ch input” (corresponding to “1” at clock signal CK) and “2ch input” (corresponding to “2” at clock signal CK) are “H” but the levels of the remaining “3ch input” and “4ch input” are “L.”

While further description is omitted, A3 through A5 at the time-divided signal are generated in similar fashion during respective intervals T3 through T5.

Such time-divided signal A is communicated from light-emitting element 4 to light-receiving element 5, the four channels of time-divided input signals being decoded (FIG. 8(g) through (j)) at output signal separation circuit 7 and being output to respective output terminals “1ch output” through “4ch output.”

Embodiment 3

Next, a third embodiment of a multichannel photocoupler in accordance with the present invention is described.

Circuit structure in the present third embodiment is identical to the circuit structure shown in FIG. 2. What is different is the fact that, in the context of operation at the foregoing second embodiment, signal transfer is carried out with “S” serving as start bit being provided at the clock signal before the first-channel signal so as to prevent bits from being dropped due to the influence of noise or the like where input signal states at respective channels are subjected to time division, this also being indicated at the timing chart in FIG. 8.

Embodiment 4

Next, a fourth embodiment of a multichannel photocoupler in accordance with the present invention is described.

In the present fourth embodiment, clock signal CK is transmitted from input side to output side as was the case at the foregoing third embodiment, but what is different from the foregoing third embodiment is the fact that signal-transfer light-emitting element 4 and light-receiving element 5 also serve as means for transferring clock signal CK from the input side to the output side. Accordingly, while circuit structure in the present fourth embodiment is itself identical to the circuit structure shown in FIG. 1, processing at input signal coupling circuit 3 is different from operation in the foregoing first embodiment corresponding to FIG. 1.

More specifically, as indicated at (k) “light-emitting element→light-receiving element signal 2” in the timing chart of FIG. 8, a signal is generated through superposition of clock signal CK of high signal level simultaneous with signals of respective channels, this signal being communicated from light-emitting element 4 to light-receiving element 5. In addition, the signal, after being amplified to constant level at amplifier circuit 6, is separated into clock signal CK and time-divided signal(s) at output signal separation circuit 7, the four channels of time-divided input signals being decoded (FIG. 8(g) through (j)) and output to respective output terminals “1ch output” through “4ch output.”

Embodiment 5

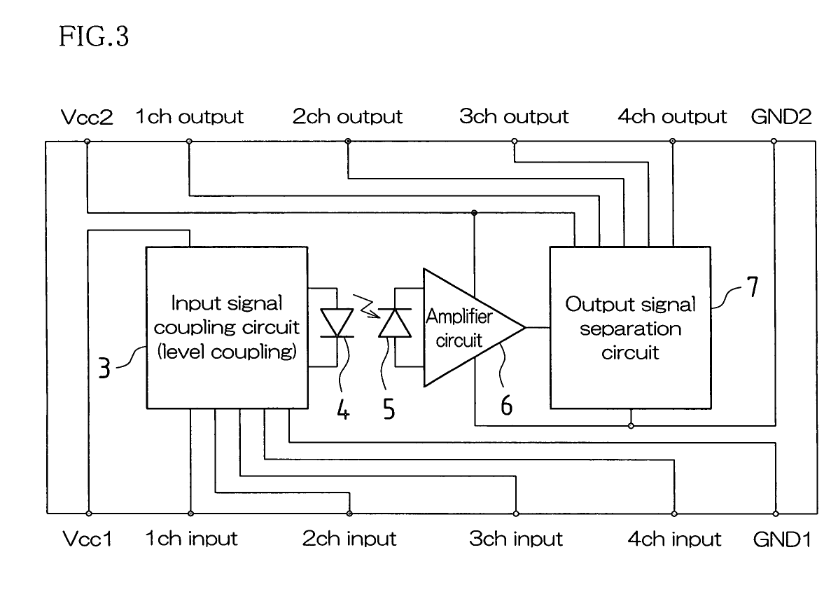

FIG. 3 is an equivalent circuit indicating a fifth embodiment of a 4-channel photocoupler associated with the present invention.

In an photocoupler in accordance with the present fifth embodiment, the input side thereof is made up of a single light-emitting element 4 transferring signal(s) to the output side thereof, and input signal coupling circuit 3 carrying out level coupling with respect to input signal(s) at respective channel(s) so as to impart change(s) in optical intensity or intensities at light-emitting element 4 and causing same to be transferred to the output side thereof; and the output side thereof is made up of a single light-receiving element 5 receiving the signal imparted with change(s) in optical intensity or intensities from light-emitting element 4, amplifier circuit 6 carrying out amplification of received the level-coupled signal so as to obtain constant level(s), and output signal separation circuit 7 decoding the amplified level-coupled signal and outputting same to respective channels.

As a result of employment of an photocoupler constituted in such fashion, input signal states at respective channels at input terminals “1ch input” through “4ch input” for the four channels at the input side are subjected to level coupling in correspondence to change in optical intensity at input signal coupling circuit 3 so as to be consolidated into a single signal (level-coupled signal) that is converted into an optical signal at light-emitting element 4 which represents the next stage, and this is then transferred to the output side. In addition, this level-coupled signal is received at light-receiving element 5 at the output side; the entirety is at amplifier circuit 6, which represents the next stage, amplified so as to be of constant level; and change(s) in optical intensity or intensities in the level-coupled signal are at output signal separation circuit 7 thereafter decoded and separated into four channels of output signals that are output to output terminals “1ch output” through “4ch output” for the corresponding respective channels.

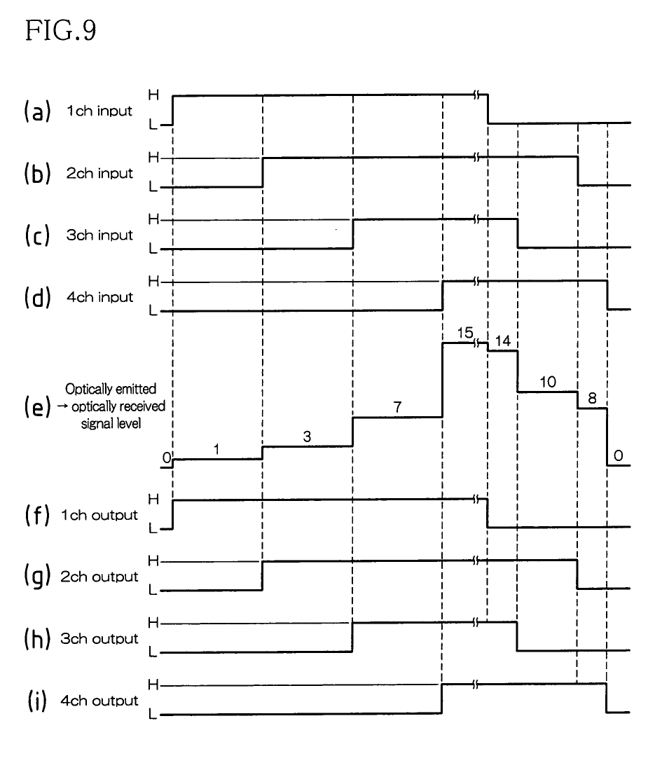

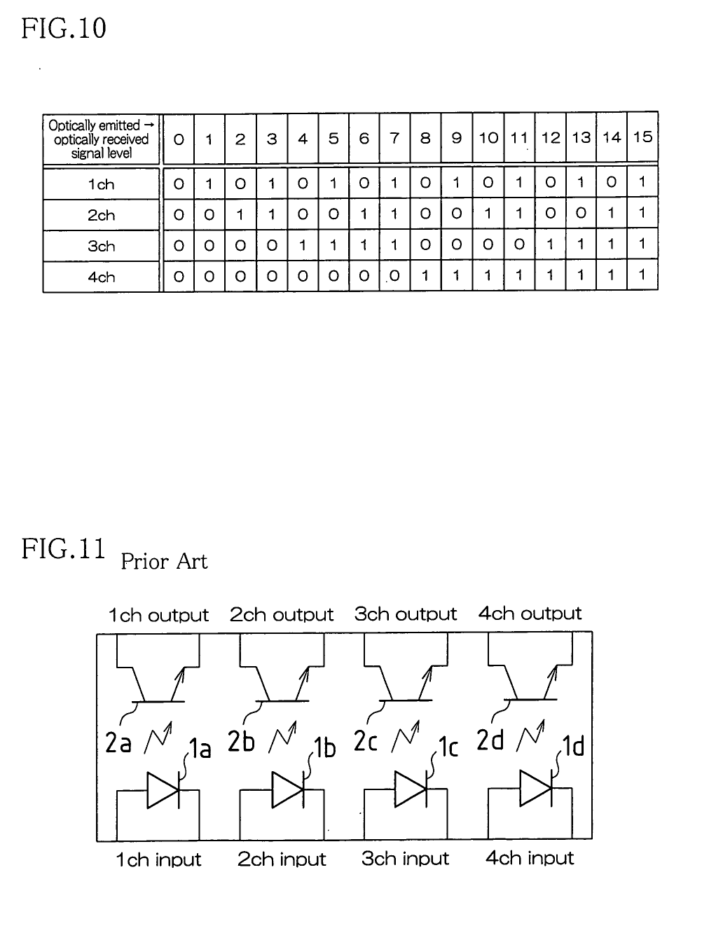

Next, referring to the timing chart shown in FIG. 9 and the “light-emitting element→light-receiving element signal level table” shown in FIG. 10, operation of a 4-channel photocoupler having the foregoing constitution is described in specific terms.

First, as indicated at the “light-emitting element→light-receiving element signal level table” of FIG. 10, signal level is divided into 16 categories from “0” to “15,” states of input signals (FIG. 9(a) through (d)) at respective channels at input terminals “1ch input” through “4ch input” for the four channels at the input side being assigned to respective levels. In addition, at input signal coupling circuit 3, level coupling is carried out in accordance with such signal levels, after the fashion of the waveform shown at “light-emitting element→light-receiving element signal level” at FIG. 9(e). This level-coupled signal is communicated from light-emitting element 4 to light-receiving element 5, the four channels of level-coupled input signals being decoded (FIG. 9(f) through (i)) at output signal separation circuit 7 and being output to respective output terminals “1ch output” through “4ch output.”

Embodiment 6

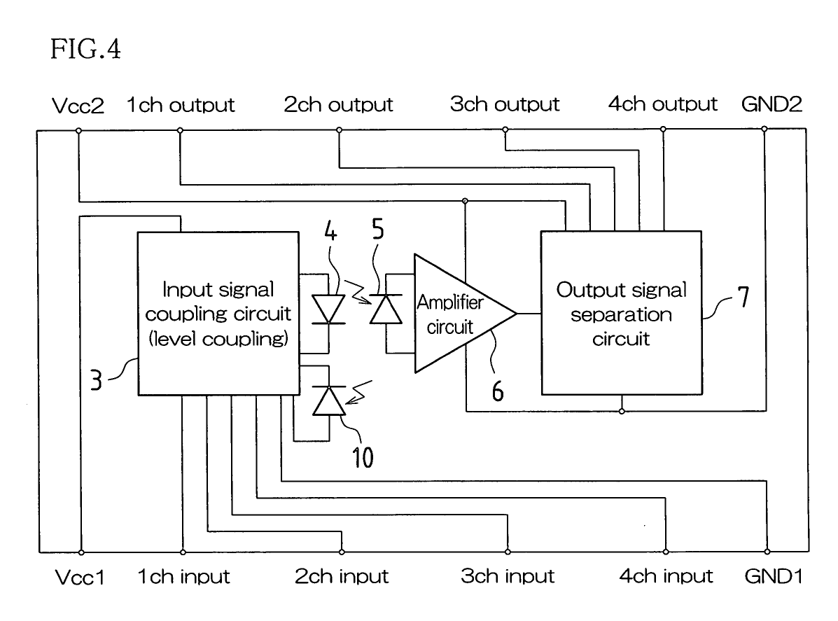

FIG. 4 is an equivalent circuit indicating a sixth embodiment of a 4-channel photocoupler associated with the present invention.

The photocoupler of the present sixth embodiment, in the context of the photocoupler of the foregoing fifth embodiment shown in FIG. 3, is provided, at the input side thereof, with separate light-receiving element 10 monitoring optical intensity or intensities at light-emitting element 4. That is, because it is conceivable that a change over time in the optical intensity at light-emitting element 4 at the input side could cause the optical signal that is transferred to the output side to change from its initial value and prevent prescribed same from being separated into respective channel(s), the present sixth embodiment is provided, at the input side thereof, with separate light-receiving element 10 monitoring the optical intensity at light-emitting element 4, change over time in the optical intensity at light-emitting element 4 being fed back to input signal coupling circuit 3 so as to make it possible for the optical intensity produced by light-emitting element 4 to be corrected so that it will always be possible to accurately carry out separation so as to yield the signals at the respective channels.

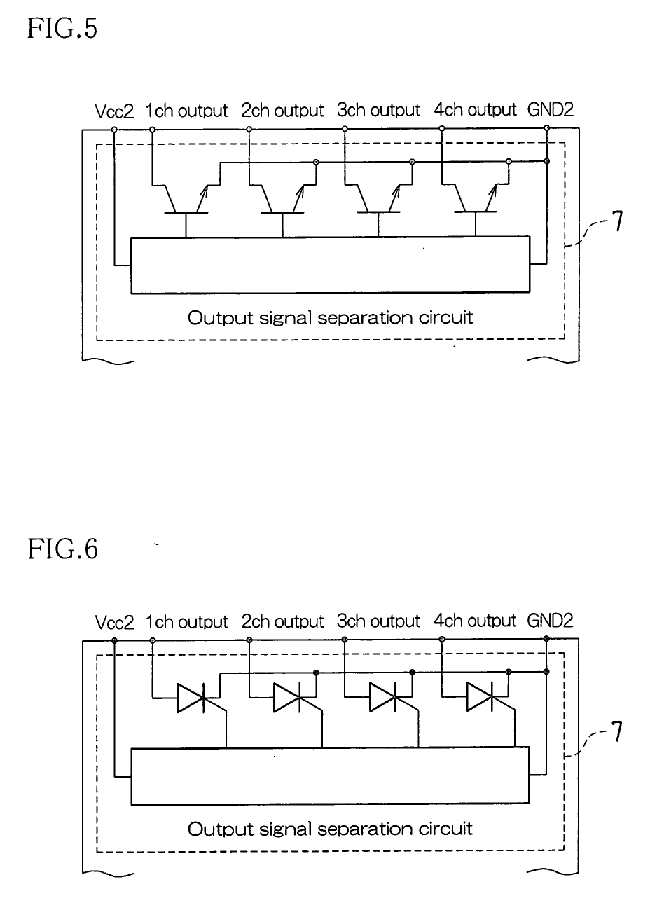

FIGS. 5 through 7 show equivalent circuits for various working examples of output stages in output signal separation circuit 7 at the foregoing respective embodiments.

In the constitution of FIG. 5, the output stage comprises transistor elements. Employment of transistor output permits connection, at the next stage, of circuits of high universality.

In the constitution of FIG. 6, the output stage comprises thyristor elements. Employment of thyristor output permits connection, at the next stage, of circuits operating on AC power or the like.

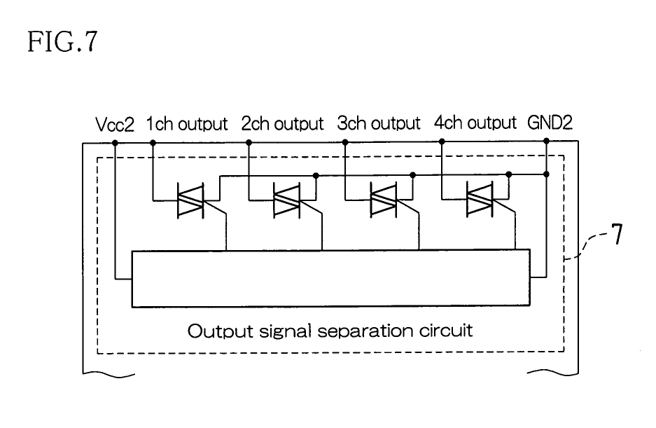

In the constitution of FIG. 7, the output stage comprises triac elements. Employment of triac output permits connection, at the next stage, of circuits operating on AC power or the like, as was the case at the foregoing working example. Furthermore, employment of triac output permits bidirectional operation.

Moreover, multichannel photocouplers in accordance with one or more embodiments of the present invention may be used in SSRs (solid-state relays) or in electronic equipment employing same or the like.

As described above, multichannel photocouplers in accordance with one or more embodiments of the present invention make it possible to consolidate light-emitting elements and/or light-receiving elements into single element(s) through employment of input signal coupling circuit(s) and output signal separation circuit(s), making it possible to dramatically reduce overall circuit parts count. It may furthermore be possible to decrease the size of the photocoupler package and/or decrease the number of pins employed by the package, making it possible to achieve a more inexpensive photocoupler. Moreover, it is possible to reduce the surface area required when mounting such an photocoupler to a board in electronic equipment or the like, permitting high-density mounting.

The present invention may be embodied in a wide variety of forms other than those presented herein without departing from the spirit or essential characteristics thereof. The foregoing embodiments and working examples, therefore, are in all respects merely illustrative and are not to be construed in limiting fashion. The scope of the present invention being as indicated by the claims, it is not to be constrained in any way whatsoever by the body of the specification. All modifications and changes within the range of equivalents of the claims are moreover within the scope of the present invention.

1. A multichannel photocoupler comprising:
at one or more input sides: one or more time division means for subjecting one or more input signals at one or more respective channels to time division; and
a light-emitting element communicating at least one of the time-divided signal or signals to one or more output sides;
at one or more output sides: a light-receiving element receiving at least one of the time-divided signal or signals from the light-emitting element; and
one or more output signal separation means for decoding at least one of the time-divided signal or signals and for outputting same to at least one of the respective channel or channels.

2. A multichannel photocoupler according to claim 1 further comprising:
one or more synchronization means for, in the event that one or more signals at at least one of the respective channel or channels is transferred from one or more input sides to one or more output sides, synchronizing the signal or signals through use of one or more prescribed clock signals.

3. A multichannel photocoupler according to claim 2 wherein:
at least one of the synchronization means at at least one of the input side or sides, in the event that one or more input signals at at least one of the respective channel or channels is subjected to time division through use of one or more prescribed clocks, generates one or more start bits before one or more signals at one or more first channels; and
at least one of the synchronization means at at least one of the output side or sides possesses functionality for detecting at least one of the start bit or bits.

4. A multichannel photocoupler according to claim 2 comprising, as one or more means for transferring one or more clock synchronization signals from one or more input sides to one or more output sides:
at at least one of the input side or sides: a clock-signal-transfer light-emitting element other than the light-emitting element for transfer of one or more signals; and
at at least one of the output side or sides: a clock-signal-transfer light-receiving element other than the light-receiving element for transfer of one or more signals.

5. A multichannel photocoupler according to claim 2 comprising, as one or more means for transferring one or more clock synchronization signals from one or more input sides to one or more output sides:
transfer of one or more clock synchronization signals simultaneous with one or more signals at at least one of the respective channel or channels through use of the light-receiving element and the light-emitting element transferring one or more signals.

6. A multichannel photocoupler according to claim 5 comprising, as one or more means for distinguishing between or among one or more clock synchronization signals and one or more signals at at least one of the respective channel or channels, one or more means:
for, at at least one of the input side or sides, varying one or more electric currents flowing at the light-emitting element so as to impart one or more differences to one or more optical intensities in one or more clock synchronization signals and one or more signals at at least one of the respective channel or channels transferred to at least one of the output side or sides, and for causing same to be transferred to at least one of the output side or sides; and
for, at at least one of the output side or sides, separating one or more signals received at the light-receiving element and having one or more differences in one or more optical intensities into one or more signals at at least one of the respective channel or channels and one or more clock synchronization signals.

7. A multichannel photocoupler comprising:
at one or more input sides: a light-emitting element transferring one or more signals to at least one of the output side or sides; and
one or more level coupling means for carrying out level coupling with respect to one or more input signals at at least one of the respective channel or channels so as to impart one or more changes in one or more optical intensities at the light-emitting element and for causing same to be transferred to at least one of the output side or sides;
at one or more output sides: a light-receiving element receiving one or more signals imparted with one or more changes in one or more optical intensities produced by the light-emitting element; and
one or more output signal separation means for decoding at least one of the signal or signals and for outputting same to at least one of the respective channel or channels.

8. A multichannel photocoupler according to claim 7 further comprising:
one or more monitor light-receiving elements provided at at least one of the input side or sides;
wherein one or more changes over time in one or more optical intensities at the light-emitting element is fed back to at least one of the level coupling means.

9. A multichannel photocoupler according to any of claims 1 through 8 wherein:
one or more output stages at at least one of the respective channel or channels comprises one or more transistor elements.

10. A multichannel photocoupler according to any of claims 1 through 8 wherein:
one or more output stages at at least one of the respective channel or channels comprises one or more thyristor elements.

11. A multichannel photocoupler according to any of claims 1 through 8 wherein:
one or more output stages at at least one of the respective channel or channels comprises one or more triac elements.

12. A multichannel photocoupler comprising:
an input circuit for receiving at least one input signal;
a time division circuit for time dividing said at least one input signal to produce a time divided signal;
an output side comprising a first light-receiving element;
a first light-emitting element communicating said time-divided signal from said input side to said output side; and
an output signal separation circuit for decoding said time-divided signal and outputting the decoded time divided signal as an output signal.

13. A multichannel photocoupler according to claim 12 further comprising a clock circuit for generating a clock signal and wherein said input circuit comprises clock signal transmitter and said output circuit comprises a clock signal receiver.

14. A multichannel photocoupler according to claim 12 further comprising a clock circuit for generating a clock signal and wherein said input circuit comprises clock signal transmitting circuit and said output circuit comprises a clock signal receiving circuit, wherein said clock signal transmitting circuit transmits a start bit and said clock signal receiving circuit is adapted to detect said start bit.

15. A multichannel photocoupler according to claim 13 wherein said clock signal transmitter comprises a second light-emitting element and said clock signal receiver comprises a second light-receiving element.

16. A multichannel photocoupler according to claim 13 wherein said clock signal transmitter comprises said first light-emitting element and wherein said clock signal receiver comprises said first light-receiving element.

17. A multichannel photocoupler according to claim 15 wherein said first light emitting element transmits light of a first intensity and said second light emitting element transmits light of a second intensity different than said first intensity.

18. A multichannel photocoupler comprising:
an input circuit for receiving at least one input signal and including a first light-emitting element;
an output circuit comprising a first light-receiving element receiving a signal from said first light-emitting element;
a level coupling circuit for level coupling said at least one input signal and changing an optical intensity at the light-emitting element; and
an output signal separation circuit for decoding and outputting said signal.
